(19) United States
(12) Patent Application Publication
(10) Pub. No.: US 2024/0055474 A1
(43) Pub. Date: Feb. 15, 2024

(54) SEMICONDUCTOR DEVICE

(71) Applicant: ROHM CO., LTD., Kyoto (JP)

(72) Inventors: Akihiro SAITO, Kyoto (JP); Kenta WATANABE, Kyoto (JP)

(73) Assignee: ROHM CO., LTD., Kyoto (JP)

(21) Appl. No.: 18/354,644

(22) Filed: Jul. 19, 2023

(30) Foreign Application Priority Data
Aug. 12, 2022 (JP) 2022-129034

(51) Int. Cl. H01L 29/06; H01L 29/40

(52) U.S. Cl. CPC H01L 29/0623; H01L 29/404; H01L 29/407

(57) ABSTRACT

A semiconductor device includes: a semiconductor layer; cell trenches formed in the semiconductor layer; an insulating layer on the semiconductor layer; electrodes, each embedded in corresponding one of the cell trenches via the insulating layer; and one or more outer peripheral trenches formed in the semiconductor layer, wherein the cell trenches include: first set of cell trenches extending in first direction and arranged at first pitch in second direction; and second set of cell trenches extending in the second direction and arranged at second pitch in the first direction, wherein the semiconductor layer includes first and second cell regions where the first and second sets of cell trenches are arranged respectively, and the one or more peripheral trenches surround the first and second cell regions in a plan view, and wherein inter-cell distance between the first and second cell regions is smaller than both the first and second pitches.

### CROSS-REFERENCE TO RELATED APPLICATION

This application is based upon and claims the benefit of priority from Japanese Patent Application No. 2022-129034, filed on Aug. 12, 2022, the entire contents of which are incorporated herein by reference.

### TECHNICAL FIELD

The present disclosure relates to a semiconductor device.

### BACKGROUND

It is known to provide a plurality of guard ring trenches around an element to improve a withstand voltage of a semiconductor device. For example, in the related art, a semiconductor device includes a semiconductor layer including an element and a periphery around the element, a semiconductor element structure formed in the element, and a plurality of guard ring trenches formed in the periphery.

### BRIEF DESCRIPTION OF DRAWINGS

The accompanying drawings, which are incorporated in and constitute a part of the specification, illustrate embodiments of the present disclosure.

FIG. 1 is a schematic plan view of an exemplary semiconductor device according to an embodiment of the present disclosure.

FIG. 2 is a schematic plan view showing an arrangement of trenches formed in a semiconductor layer of the semiconductor device shown in FIG. 1.

FIG. 3 is a schematic cross-sectional view of the semiconductor device taken along line F3-F3 in FIG. 2.

FIG. 4 is an enlarged view of the semiconductor device in a region indicated by F4 in FIG. 2.

FIG. 5 is a schematic cross-sectional view of the semiconductor device taken along line F5-F5 in FIG. 4.

FIG. 6 is a graph showing a breakdown voltage of a semiconductor device in an experimental example.

FIG. 7 is a schematic plan view of an exemplary semiconductor device according to a first modification.

FIG. 8 is a schematic plan view showing an arrangement of trenches formed in a semiconductor layer of the semiconductor device shown in FIG. 7.

FIG. 9 is a schematic plan view of an exemplary semiconductor device according to a second modification.

FIG. 10 is a schematic plan view showing an arrangement of trenches formed in a semiconductor layer of the semiconductor device shown in FIG. 9.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Some embodiments of a semiconductor device of the present disclosure will be described below with reference to the accompanying drawings. It should be noted that, for simplicity and clarity of explanation, components shown in the drawings may not be drawn to scale. To facilitate understanding, hatching lines may be omitted in cross-sectional views. The accompanying drawings merely illustrate embodiments of the present disclosure and should not be considered as limiting the present disclosure.

The following detailed description includes devices, systems, and methods embodying exemplary embodiments of the present disclosure. This detailed description is merely illustrative in nature and is not intended to limit the embodiments of the disclosure or the applications and uses of such embodiments.

### (Planar Layout of Semiconductor Device)

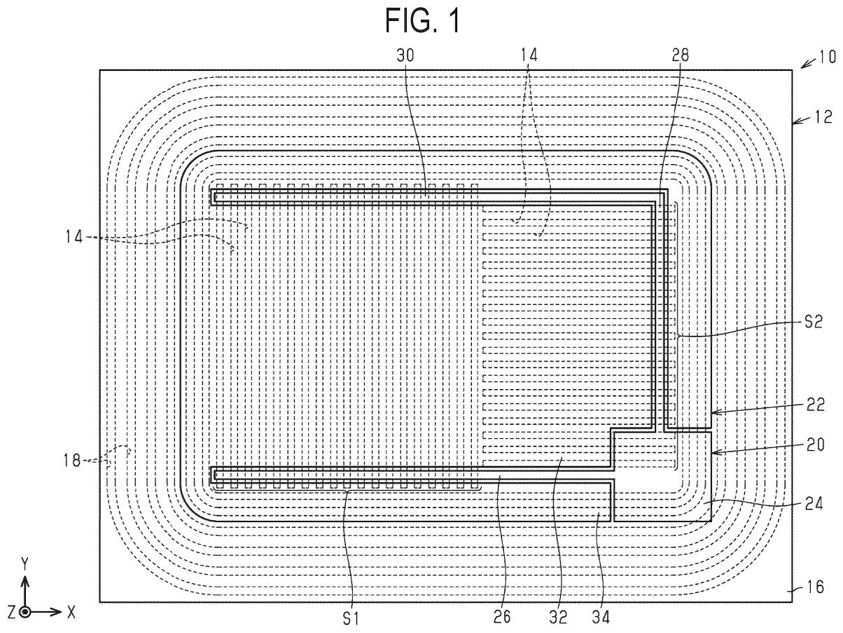

FIG. 1 is a schematic plan view of an exemplary semiconductor device 10 according to an embodiment of the present disclosure. The semiconductor device 10 may be, for example, a metal insulating film semiconductor field effect transistor (MISFET) with a trench gate structure. The semiconductor device 10 includes a semiconductor layer 12, a plurality of cell trenches 14 formed in the semiconductor layer 12, and an insulating layer 16 formed on the semiconductor layer 12. Among an X-axis direction, a Y-axis direction, and a Z-axis direction, which are orthogonal to one another as shown in FIG. 1, the Z-axis direction is a direction orthogonal to a surface of the semiconductor layer 12. The term “plan view” used in the present disclosure refers to viewing the semiconductor device 10 from above along the Z-axis direction, unless otherwise specified.

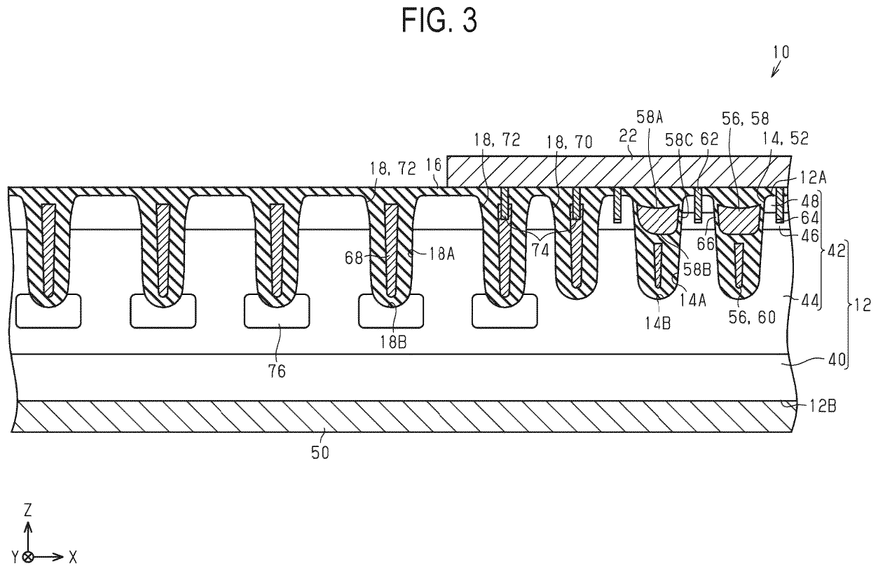

In FIG. 1, since the semiconductor layer 12 is covered with the insulating layer 16, reference numeral 12 indicates an outer edge of the semiconductor layer 12. A region defined by the outer edge of the semiconductor layer 12 shown in FIG. 1 may correspond to one chip (die). Details of the semiconductor layer 12 will be described later with reference to FIG. 3. The insulating layer 16 may include at least one of a silicon oxide (SiO₂) layer and a silicon nitride (SiN) layer.

The plurality of cell trenches 14 includes a first set of cell trenches S1 extending in the Y-axis direction and arranged in the X-axis direction, and a second set of cell trenches S2 extending in the X-axis direction and arranged in the Y-axis direction. In the present disclosure, the Y-axis direction may be referred to as a first direction, and the X-axis direction may be referred to as a second direction. That is, the second direction is orthogonal to the first direction in a plan view. In the example of FIG. 1, the cell trenches 14 included in the first set may have the same length. Further, the cell trenches 14 included in the second set may have the same length. The semiconductor device 10 further includes one or more outer peripheral trenches 18 formed in semiconductor layer 12. The one or more outer peripheral trenches 18 may be arranged to surround the plurality of cell trenches 14.

The semiconductor device 10 may further include a gate wiring 20 formed on the insulating layer 16 and a source wiring 22 formed on the insulating layer 16 and separated from the gate wiring 20. The gate wiring 20 and the source wiring 22 may be made of at least one of titanium (Ti), nickel (Ni), gold (Au), silver (Ag), copper (Cu), aluminum (Al), a copper alloy, and an aluminum alloy.

The gate wiring 20 may include a gate pad 24 arranged at one corner of the semiconductor layer 12, and gate fingers 26, 28, and 30 in a plan view. The gate finger 26 may extend from the gate pad 24 in the X-axis direction and overlap some of the plurality of cell trenches 14 in a plan view. The gate finger 28 may extend from the gate pad 24 in the Y-axis direction and overlap some of the plurality of cell trenches 14 in a plan view. The gate finger 30 may extend from the gate finger 28 in the X-axis direction and overlap some of the plurality of cell trenches 14 in a plan view. The gate pad 24 and the gate fingers 26, 28, and 30 may be integrally formed. The source wiring 22 may include an inner segment 32 at least partially surrounded by the gate wiring 20 in a plan view and an outer peripheral segment 34 at least partially surrounding the gate wiring 20. The inner segment 32 is connected to the outer peripheral segment 34 via a gap between the gate finger 26 and the gate finger 30. The inner segment 32 and the outer peripheral segment 34 may be integrally formed.

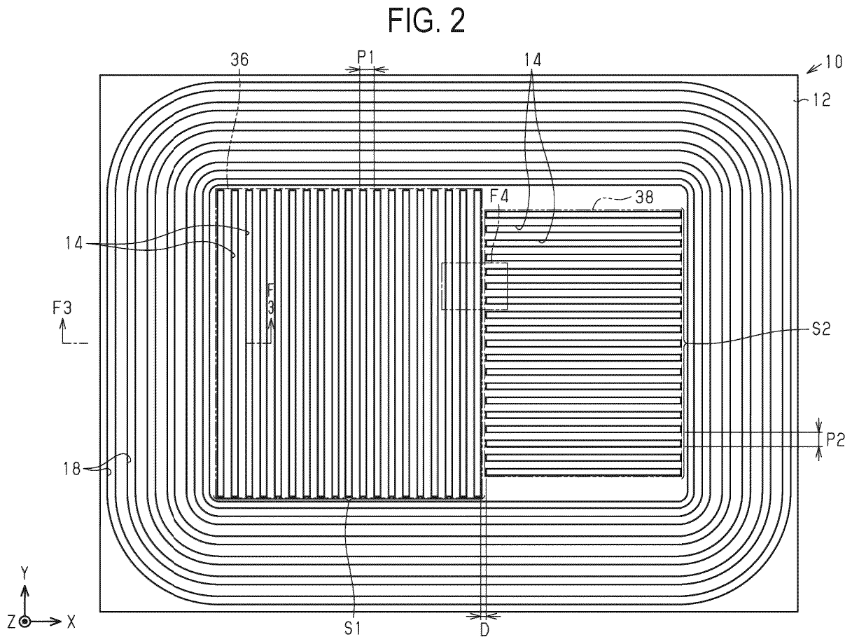

FIG. 2 is a schematic plan view showing an arrangement of cell trenches 14 and outer peripheral trenches 18 formed in the semiconductor layer 12 of the semiconductor device 10 shown in FIG. 1. For explaining the arrangement of cell trenches 14 and outer peripheral trenches 18, the insulating layer 16, the gate wiring 20, and the source wiring 22 (see FIG. 1) are omitted in the semiconductor device 10 shown in FIG. 2.

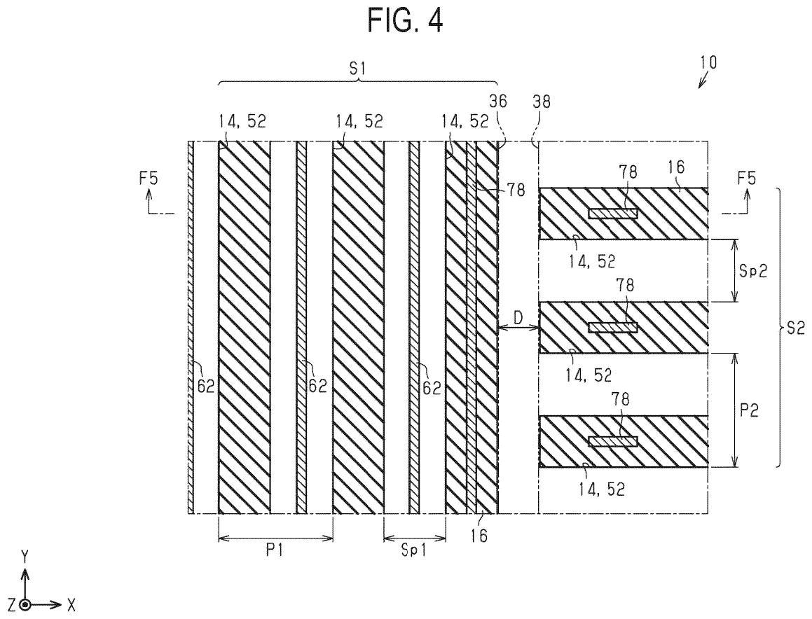

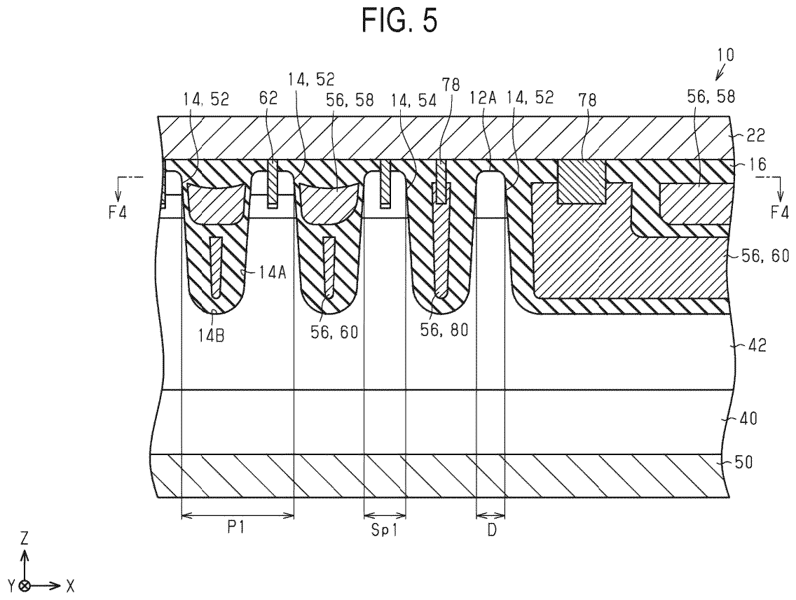

The first set of cell trenches S1 is arranged at a first pitch P1 in the X-axis direction in a plan view. The second set of cell trenches S2 is arranged at a second pitch P2 in the Y-axis direction in a plan view. The semiconductor layer 12 includes a first cell region 36 in which the first set of cell trenches S1 is arranged, and a second cell region 38 in which the second set of cell trenches S2 is arranged. Each of the first cell region 36 and the second cell region 38 may be rectangular in a plan view. In the example of FIG. 2, the first cell region 36 and the second cell region 38 may be arranged in the X-axis direction. One or more outer peripheral trenches 18 are arranged to surround the first cell region 36 and the second cell region 38 in a plan view. More specifically, the one or more outer peripheral trenches 18 may form a loop surrounding the first cell region 36 and the second cell region 38 in a plan view. An inter-cell distance D between the first cell region 36 and the second cell region 38 is smaller than either of the first pitch P1 and the second pitch P2. Further details of the inter-cell distance D will be described later with reference to FIGS. 4 and 5.

### (Cross-sectional Structures of Cell Trench and Outer Peripheral Trench)

First, the cross-sectional structures of the cell trench 14 and the outer peripheral trench 18 will be described with reference to FIG. 3. FIG. 3 is a schematic cross-sectional view of the semiconductor device taken along line F3-F3 in FIG. 2. FIG. 3 shows a portion of the cell trench 14 arranged in the first cell region 36, and six outer peripheral trenches 18.

The semiconductor layer 12 includes a top surface 12A and a bottom surface 12B opposite the top surface 12A. The Z-axis direction may be a direction orthogonal to the top surface 12A and the bottom surface 12B of the semiconductor layer 12. The semiconductor layer 12 may include a semiconductor substrate 40 and an epitaxial layer 42 formed on the semiconductor substrate 40. The semiconductor substrate 40 may include the bottom surface 12B of the semiconductor layer 12. The epitaxial layer 42 may include the top surface 12A of the semiconductor layer 12. In the present embodiment, the semiconductor substrate 40 may be a Si substrate. Further, the epitaxial layer 42 may be a Si epitaxial layer. The semiconductor substrate 40 may correspond to a drain region of MISFET.

In the first cell region 36 and the second cell region 38 (see FIG. 2) in which the cell trenches 14 are arranged, the epitaxial layer 42 includes a drift region 44 formed on the semiconductor substrate 40 (drain region), a body region 46 formed on the drift region 44, and a source region 48 formed on the body region 46.

The drain region formed by the semiconductor substrate 40 may be an n-type region containing n-type impurities. An n-type impurity concentration of the semiconductor substrate 40 may be 1×10¹⁸ cm⁻³ or more and 1×10²⁰ cm⁻³ or less. The semiconductor substrate 40 may have a thickness of 50 μm or more and 450 μm or less.

The drift region 44 may be an n-type region containing a lower concentration of n-type impurities than the semiconductor substrate 40 (drain region). The n-type impurity concentration of the drift region 44 may be 1×10¹⁵ cm⁻³ or more and 1×10¹⁸ cm⁻³ or less. The drift region 44 may have a thickness of 1 μm or more and 25 μm or less.

The body region 46 may be a p-type region containing p-type impurities. A p-type impurity concentration of the body region 46 may be 1×10¹⁶ cm⁻³ or more and 1×10¹⁸ cm⁻³ or less. The body region 46 may have a thickness of 0.2 μm or more to 1.0 μm or less.

The source region 48 may be an n-type region containing a higher concentration of n-type impurities than the drift region 44. The n-type impurity concentration of the source region 48 may be 1×10¹⁹ cm⁻³ or more and 1×10²¹ cm⁻³ or less. The source region 48 may have a thickness of 0.1 μm or more to 1 μm or less.

In the present disclosure, the n-type is also referred to as a first conductivity type, and the p-type is also referred to as a second conductivity type. The n-type impurity may be, for example, phosphorus (P), arsenic (As), or the like. Further, the p-type impurity may be, for example, boron (B), aluminum (Al), or the like.

The semiconductor device 10 may further include a drain electrode 50 formed on the bottom surface 12B of the semiconductor layer 12. The drain electrode 50 is electrically connected to the semiconductor substrate 40 (drain region). The drain electrode 50 may be made of at least one of titanium (Ti), nickel (Ni), gold (Au), silver (Ag), copper (Cu), Al, a Cu alloy, and an Al alloy.

The cell trench 14 has an opening in the top surface 12A of the semiconductor layer 12, and a depth in the Z-axis direction. The cell trench 14 has a sidewall 14A and a bottom wall 14B. The cell trench 14 reaches the drift region 44 through the source region 48 and the body region 46 of the epitaxial layer 42. Therefore, the bottom wall 14B of the cell trench 14 is adjacent to the drift region 44. The cell trench 14 may have a depth of 1 μm or more and 10 μm or less. The depth of the cell trench 14 may correspond to a distance in the Z-axis direction from the top surface 12A of the semiconductor layer 12 to the bottom wall 14B of the cell trench 14.

The sidewall 14A of the cell trench 14 may extend in the Z-axis direction (a direction perpendicular to the top surface 12A of the semiconductor layer 12) or may be inclined with respect to the Z-axis direction. For example, the sidewall 14A may be inclined with respect to the Z-axis direction such that the width of the cell trench 14 decreases as it approaches the bottom wall 14B. Further, the bottom wall 14B of the cell trench 14 may not be flat, and may be, for example, partially or wholly curved.

The plurality of cell trenches 14 may include a plurality of gate trenches 52 and field plate trenches 54 (see FIGS. 4 and 5). The cell trenches 14 shown in FIG. 3 correspond to the gate trenches 52. The field plate trenches 54 will be described later with reference to FIGS. 4 and 5.

The semiconductor device 10 further includes a plurality of electrodes 56. In an example, the plurality of electrodes 56 may be formed from conductive polysilicon. In another example, the plurality of electrodes 56 may be formed from any other metallic material. Each of the plurality of electrodes 56 is embedded in a corresponding one of the plurality of cell trenches 14 via the insulating layer 16. The plurality of electrodes 56 may include a plurality of gate electrodes 58. Each of the plurality of gate electrodes 58 may be embedded in a corresponding one of the plurality of gate trenches 52 via the insulating layer 16. In the present disclosure, the gate trench 52 refers to a cell trench 14 in which a gate electrode 58 is embedded. The plurality of gate electrodes 58 is electrically connected to the gate wiring 20.

Further, the plurality of electrodes 56 may further include a plurality of first field plate electrodes 60. Each of the plurality of first field plate electrodes 60 may be embedded in a corresponding one of the plurality of gate trenches 52 via the insulating layer 16 while being separated from the gate electrode 58. The plurality of first field plate electrodes 60 is electrically connected to the source wiring 22.

The gate electrode 58 may be configured such that a gate voltage is applied to the gate electrode 58, and the first field plate electrode 60 may be configured such that a reference voltage (or source voltage) is applied to the first field plate electrode 60.

The gate electrode 58 may include a top surface 58A covered with the insulating layer 16 and a bottom surface 58B opposite the top surface 58A. The first field plate electrode 60 is arranged below the gate electrode 58 within the gate trench 52. More specifically, the first field plate electrode 60 may be arranged between the bottom surface 58B of the gate electrode 58 and the bottom wall 14B of the gate trench 52. At least a portion of the bottom surface 58B of the gate electrode 58 faces the first field plate electrode 60 with the insulating layer 16 interposed therebetween. The gate electrode 58 further includes a side surface 58C facing the sidewall 14A of the gate trench 52.

The top surface 58A of the gate electrode 58 may be located below the top surface 12A of the semiconductor layer 12. Further, the bottom surface 58B of the gate electrode 58 may be located near an interface between the drift region 44 and the body region 46 in the Z-axis direction, and may be below the interface. The top surface 58A and the bottom surface 58B of the gate electrode 58 may be flat or curved.

The gate electrode 58 and the first field plate electrode 60 are surrounded by the insulating layer 16. The first field plate electrode 60 may have a smaller width than the gate electrode 58. Due to the relatively small width of the first field plate electrode 60, the thickness of the insulating layer 16 surrounding the first field plate electrode 60 is relatively large.

Thus, in the example of FIG. 3, two electrodes 56, namely, the gate electrode 58 and the first field plate electrode 60, may be embedded in the gate trench 52. In another example, only the gate electrode 58 may be embedded in the gate trench 52.

The semiconductor device 10 may further include a plurality of source contact plugs 62 connected to the source wiring 22. Each source contact plug 62 may extend parallel to the gate trench 52 in a plan view. In an example, one gate trench 52 may be arranged between two source contact plugs 62.

The epitaxial layer 42 may further include a contact region 64. The contact region 64 may be a p-type region containing p-type impurities. The p-type impurity concentration of the contact region 64 may be higher than that of the body region 46 and may be 1×10¹⁹ cm⁻³ or more and 1×10²¹ cm⁻³ or less. The source contact plug 62 extends through the insulating layer 16 and the source region 48 to contact the contact region 64. The contact region 64 is electrically connected to the source wiring 22 via the source contact plug 62.

The insulating layer 16 includes a gate insulating portion 66 interposed between the gate electrode 58 and the semiconductor layer 12 and covering the sidewall 14A of the gate trench 52. The gate insulating portion 66 is a portion of the insulating layer 16 between the side surface 58C of the gate electrode 58 and the sidewall 14A of the gate trench 52. The gate electrode 58 faces the semiconductor layer 12 via the gate insulating portion 66. When a predetermined voltage is applied to the gate electrode 58, a channel is formed in the p-type body region 46 adjacent to the gate insulating portion 66. The semiconductor device 10 may allow control of electron flow in the Z-axis direction between the n-type source region 48 and the n-type drift region 44 via this channel. Further, since the first field plate electrode 60 is electrically connected to the source wiring 22, electric field concentration in the gate trench 52 may be alleviated, thereby improving a withstand voltage of the semiconductor device 10.

As described above, one or more outer peripheral trenches 18 are arranged to surround the first cell region 36 and the second cell region 38 in a plan view. Six outer peripheral trenches 18 located around the first cell region 36 are shown in FIG. 3. Each outer peripheral trench 18 has an opening in the top surface 12A of the semiconductor layer 12, and has a depth in the Z-axis direction. The outer peripheral trench 18 has a sidewall 18A and a bottom wall 18B. The sidewall 18A of the outer peripheral trench 18 may extend in the Z-axis direction (a direction perpendicular to the top surface 12A of the semiconductor layer 12), or may be inclined with respect to the Z-axis direction. In an example, the sidewall 18A may be inclined with respect to the Z-axis direction such that the width of the outer peripheral trench 18 decreases as it approaches the bottom wall 18B. Further, the bottom wall 18B of the outer peripheral trench 18 may not be flat, and may be, for example, partially or entirely curved.

The semiconductor device 10 may further include one or more outer peripheral electrodes 68. Each of the one or more outer peripheral electrodes 68 may be embedded in a corresponding one of the one or more outer peripheral trenches 18 via the insulating layer 16.

When the one or more outer peripheral trenches 18 include a plurality of outer peripheral trenches 18, the plurality of outer peripheral trenches 18 may include the innermost first outer peripheral trench 70 and one or more second outer peripheral trenches 72 surrounding the first outer peripheral trench 70 in a plan view, among the plurality of outer peripheral trenches 18. The first outer peripheral trench 70 may be located between the cell trench 14 and the one or more second outer peripheral trenches 72. In FIG. 3, the first outer peripheral trench 70 is located between the gate trench 52 and the second outer peripheral trenches 72.

In an example, each of the one or more second outer peripheral trenches 72 may have a width greater than that of the first outer peripheral trench 70. In this case, the depth of each second outer peripheral trench 72 may be greater than the depth of the first outer peripheral trench 70. Further, in this case, the first outer peripheral trench 70 may have the same width as the cell trench 14. In another example, each of the one or more second outer peripheral trenches 72 may have the same width as the first outer peripheral trench 70.

The one or more second outer peripheral trenches 72 may be arranged at a pitch larger than a pitch at which the gate trenches 52 are arranged. Further, a pitch at which the first outer peripheral trench 70 and the second outer peripheral trenches 72 are arranged may be smaller than the pitch at which the gate trenches 52 are arranged.

At least one selected from the group of the one or more outer peripheral electrodes 68 may be electrically connected to the source wiring 22. The semiconductor device 10 may further include a plurality of outer peripheral contacts 74 configured to connect at least one selected from the group of the plurality of outer peripheral electrodes 68 to the source wiring 22. In the example of FIG. 3, two outer peripheral contacts 74 connect an outer peripheral electrode 68 embedded in the first outer peripheral trench 70 and an outer peripheral electrode 68 embedded in a second outer peripheral trench 72 located near the first outer peripheral trench 70, respectively, to the source wiring 22. In this example, the outer peripheral electrode 68 embedded in each of other four second outer peripheral trenches 72 may not be connected to the outer peripheral contacts 74. In another example, all of the plurality of outer peripheral electrodes 68 embedded in the plurality of outer peripheral trenches 18 may be connected to the source wiring 22 via the outer peripheral contacts 74.

The epitaxial layer 42 may further include a high-concentration region 76 in the vicinity of the bottom wall 14B of each second outer peripheral trench 72. The high-concentration region 76 may be an n-type region containing a higher concentration of n-type impurities than the drift region 44. The high-concentration region 76 may suppress electric field concentration in the vicinity of the bottom wall 14B.

### (Inter-cell Distance)

FIG. 4 is an enlarged view of the semiconductor device 10 in a region indicated by F4 in FIG. 2. FIG. 5 is a schematic cross-sectional view of the semiconductor device taken along line F5-F5 in FIG. 4. FIG. 4 may correspond to a cross-sectional view of the semiconductor device 10 at a position below the top surface 12A of the semiconductor layer 12 (see line F4-F4 in FIG. 5).

The first set of cell trenches S1 is arranged at the first pitch P1 in the X-axis direction in a plan view. Further, the first set of cell trenches S1 may be arranged at a first spacing Sp1. The first spacing Sp1 may correspond to the first pitch P1 minus the width of the cell trench 14 (the width of the cell trench 14 in the transverse direction).

The second set of cell trenches S2 is arranged at the second pitch P2 in the Y-axis direction in a plan view. Further, the second set of cell trenches S2 may be arranged at a second spacing Sp2. The second spacing Sp2 may correspond to the second pitch P2 minus the width of the cell trench 14 (the dimension of the cell trench 14 in the transverse direction).

The first pitch P1 may be the same as the second pitch P2. Further, the first spacing Sp1 may be the same as the second spacing Sp2. In another example, the first pitch P1 may be different from the second pitch P2. For example, the first pitch P1 may be larger or smaller than the second pitch P2. Further, the first spacing Sp1 may be different from the second spacing Sp2.

As described above, the inter-cell distance D between the first cell region 36 and the second cell region 38 is smaller than both the first pitch P1 and the second pitch P2. The inter-cell distance D may be a minimum distance between the first set of cell trenches S1 and the second set of cell trenches S2. More specifically, when the first cell region 36 and the second cell region 38 are arranged in the X-axis direction, the inter-cell distance D may be the minimum distance between one cell trench located closest to the second cell region 38 among the first set of cell trenches S1 and two or more cell trenches among the second set of cell trenches S2.

In an example, the inter-cell distance D may be smaller than both the first spacing Sp1 and the second spacing Sp2. In another example, the inter-cell distance D may be equal to or larger than the first spacing Sp1 or the second spacing Sp2.

In the example shown in FIG. 5, as the inter-cell distance D, the first pitch P1, the second pitch P2, the first spacing Sp1, and the second spacing Sp2, dimensions measured at positions below the top surface 12A of the semiconductor layer 12 and above the gate electrode 58 are adopted. In another example, as the inter-cell distance D, the first pitch P1, the second pitch P2, the first spacing Sp1, and the second spacing Sp2, dimensions measured at a position of the top surface 12A of the semiconductor layer 12 may be adopted. In still another example, as the inter-cell distance D, the first pitch P1, the second pitch P2, the first spacing Sp1, and the second spacing Sp2, dimensions measured at a predetermined depth position of the cell trench 14 may be adopted. Here, the predetermined depth position of the cell trench 14 may be, for example, a position below the upper surface 12A of the semiconductor layer 12 by 10% of the depth of the cell trench 14, a position below the upper surface 12A of the semiconductor layer 12 by 50% of the depth of the cell trench 14, or the like. Further, the depth of the cell trench 14 may correspond to the distance in the Z-axis direction from the top surface 12A of the semiconductor layer 12 to the bottom wall 14B of the cell trench 14.

As shown in FIG. 4, among the first set of cell trenches S1 arranged in the first cell region 36, the cell trench 14 arranged closest to the second cell region 38 may be the field plate trench 54. The semiconductor device 10 may include a plurality of field plate contact plugs 78. The plurality of field plate contact plugs 78 may be arranged to overlap ends of the second set of cell trenches S2 (ends of the gate trenches 52) and the field plate trench 54.

As shown in FIG. 5, the first field plate electrode 60 may be connected to the source wiring 22 via the field plate contact plug 78. Further, the plurality of electrodes 56 may each include a second field plate electrode 80, and the second field plate electrode 80 may be embedded in the field plate trench 54 via the insulating layer 16. The second field plate electrode 80 is electrically connected to the source wiring 22. The second field plate electrode 80 may be configured such that a reference voltage (or source voltage) is applied to the second field plate electrode 80. The second field plate electrode 80 may be connected to the source wiring 22 via the field plate contact plug 78. The second field plate electrode 80 is embedded in the field plate trench 54, but the gate electrode 58 is not embedded therein.

In another example, among the first set of cell trenches S1 arranged in the first cell region 36, the cell trench 14 arranged closest to the second cell region 38 may also be the gate trench 52. In that case, the cell trench 14 may not include the field plate trench 54.

In still another example, the cell trench 14 may include a plurality of field plate trenches 54. Each of the plurality of field plate trenches 54 may be arranged in the vicinity of the ends of the first cell region 36 and/or the second cell region 38.

### (Operation of Semiconductor Device)

The operation of the semiconductor device 10 of the present embodiment will be described below. The semiconductor layer 12 includes the first cell region 36 in which the first set of cell trenches S1 is arranged, and the second cell region 38 in which the second set of cell trenches S2 is arranged. The first set of cell trenches S1 extends in the Y-axis direction (the first direction) and is arranged at the first pitch P1 in the X-axis direction (the second direction) in a plan view. The second set of cell trenches S2 extends in the X-axis direction (the second direction) and is arranged at the second pitch P2 in the Y-axis direction (the first direction).

To secure the withstand voltage of the semiconductor device 10, in the related art, the first cell region 36 and the second cell region 38 may be surrounded by separate outer peripheral structures, respectively. However, when the first cell region 36 and the second cell region 38 are surrounded by the separate outer peripheral structures, respectively, since ratios of the outer peripheral structures on the semiconductor layer 12 increase, an active region (cell region) of the semiconductor device 10 becomes smaller. This may affect performance (e.g., on-resistance) of the semiconductor device 10.

In this respect, according to the semiconductor device 10 of the present embodiment, one or more outer peripheral trenches 18 are arranged to surround the first cell region 36 and the second cell region 38 in a plan view. As a result, since the first cell region 36 and the second cell region 38 may be made relatively wide, the on-resistance of the semiconductor device 10 may be reduced.

Further, the inter-cell distance D between the first cell region 36 and the second cell region 38 is smaller than both the first pitch P1 and the second pitch P2. As a result, the withstand voltage of the semiconductor device 10 may be ensured, as will be described below, without surrounding the first cell region 36 and the second cell region 38 with separate outer peripheral structures, respectively.

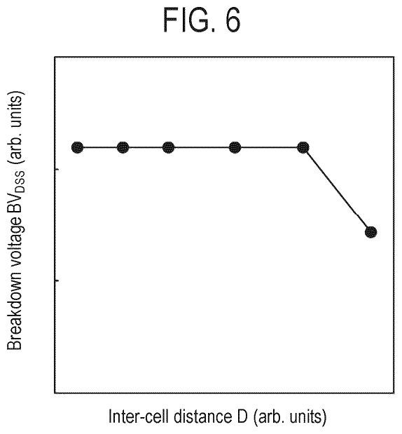

FIG. 6 is a graph showing a breakdown voltage BV_{DSS} of a semiconductor device in an experimental example, a horizontal axis of the graph corresponds to the inter-cell distance D, and a vertical axis of the graph corresponds to the breakdown voltage BV_{DSS}. The breakdown voltage BV_{DSS} is a drain-source voltage measured by applying a predetermined drain current while short-circuiting between the gate and the source. As shown in FIG. 6, in a semiconductor device with a relatively small inter-cell distance D, although the breakdown voltage BV_{DSS} has a relatively large value, the breakdown voltage BV_{DSS} decreases when the inter-cell distance D increases beyond a certain level. The inventors of the present disclosure found that the breakdown voltage BV_{DSS} equivalent to that obtained when the first cell region 36 and the second cell region 38 are surrounded by the separate outer peripheral structures, respectively, may be obtained by making the inter-cell distance D smaller than both the first pitch P1 and the second pitch P2. This may be because a depletion layer formed in a region between the first cell region 36 and the second cell region 38 may be widened in the same manner as the cell regions 36 and 38 by making the inter-cell distance D smaller than both the first pitch P1 and the second pitch P2.

By making the inter-cell distance D smaller than both the first pitch P1 and the second pitch P2, the inter-cell distance D may be significantly reduced (e.g., by approximately one digit) as compared with the case where the first cell region 36 and the second cell region 38 are surrounded by the separate outer peripheral structures, respectively.

As described above, in the semiconductor device 10 of the present embodiment, one or more outer peripheral trenches 18 are arranged to surround the first cell region 36 and the second cell region 38 in a plan view, and the inter-cell distance D between the first cell region 36 and the second cell region 38 is smaller than both the first pitch P1 and the second pitch P2. As a result, the depletion layer formed in the region between the first cell region 36 and the second cell region 38 may be widened in the same manner as in the cell regions 36 and 38, and the cell regions 36 and 38 may be relatively widened. Therefore, the on-resistance of the semiconductor device 10 may be reduced while ensuring the withstand voltage of the semiconductor device 10.

The semiconductor device 10 of the present embodiment has the following advantages.
(1) One or more outer peripheral trenches 18 are arranged to surround the first cell region 36 and the second cell region 38 in a plan view, and the inter-cell distance D between the first cell region 36 and the second cell region 38 is smaller than both the first pitch P1 and the second pitch P2. As a result, the depletion layer formed in the region between the first cell region 36 and the second cell region 38 may be widened in the same manner as in the cell regions 36 and 38, and the cell regions 36 and 38 may be relatively widened. Therefore, the on-resistance of the semiconductor device 10 may be reduced while ensuring the withstand voltage of the semiconductor device 10.
(2) The inter-cell distance D may be smaller than both the first spacing Sp1 and the second spacing Sp2. As a result, the withstand voltage of the semiconductor device 10 may also be stably ensured.
(3) The plurality of electrodes 56 includes the plurality of first field plate electrodes 60, and each of the plurality of first field plate electrodes 60 is embedded in the corresponding one among the plurality of gate trenches 52 via the insulating layer 16 while being separated from the gate electrode 58. As a result, an electric field concentration in the gate trench 52 may be alleviated, and a gate-drain capacitance may be reduced.
(4) The plurality of cell trenches 14 includes the field plate trench 54, the plurality of electrodes 56 includes the second field plate electrode 80 embedded in the field plate trench 54 via the insulating layer 16, and the gate electrode 58 is not embedded in the field plate trench 54. By providing such a field plate trench 54, the withstand voltage of the semiconductor device 10 may be improved.
(5) The first cell region 36 and the second cell region 38 are arranged in the X-axis direction (the second direction), and the cell trench 14 located closest to the second cell region 38 among the first set of cell trenches S1 may be the field plate trench 54. As a result, the withstand voltage in the region between the first cell region 36 and the second cell region 38 may be further improved.

### [First Modification]

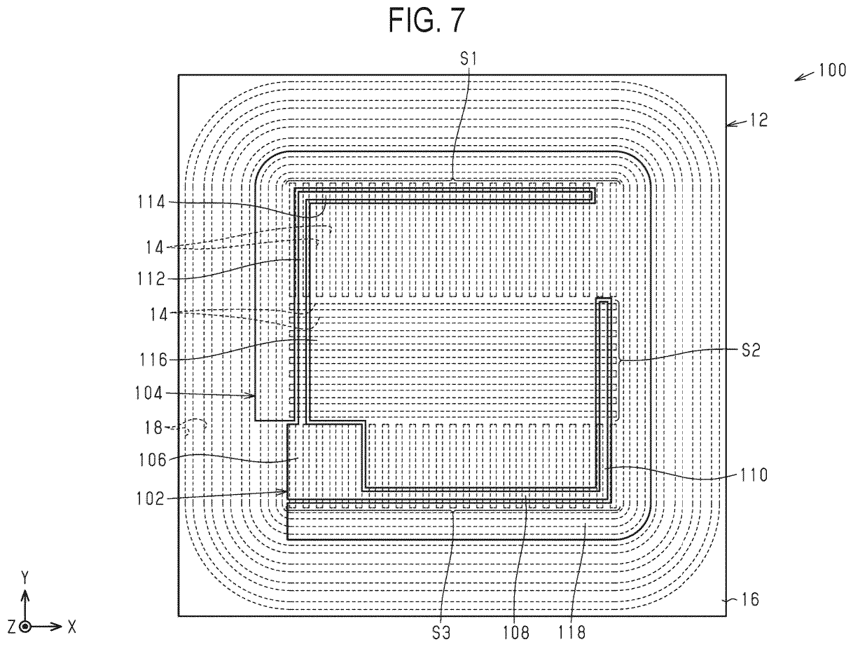

FIG. 7 is a schematic plan view of an exemplary semiconductor device 100 according to a first modification. In FIG. 7, the same components as those of the semiconductor device 10 shown in FIG. 1 are denoted by the same reference numerals. Detailed explanation of the same components as those of the semiconductor device 10 are omitted.

In the same manner as the semiconductor device 10, the semiconductor device 100 may be, for example, a metal insulating film semiconductor field effect transistor (MISFET) with a trench gate structure. The semiconductor device 100 includes a semiconductor layer 12, a plurality of cell trenches 14 formed in the semiconductor layer 12, and an insulating layer 16 formed on the semiconductor layer 12.

The plurality of cell trenches 14 includes a first set of cell trenches S1 extending in the Y-axis direction and arranged in the X-axis direction, a second set of cell trenches S1 extending in the X-axis direction and arranged in the Y-axis direction, and a third set of cell trenches S3 extending in the Y-axis direction and arranged in the X-axis direction. In the example of FIG. 7, the cell trenches 14 included in the first set may have the same length. The cell trenches 14 included in the second set may have the same length. The cell trenches 14 included in the third set may have the same length. The semiconductor device 100 further includes one or more outer peripheral trenches 18 formed in the semiconductor layer 12. The one or more outer peripheral trenches 18 may be arranged to surround the plurality of cell trenches 14.

The cross-sectional structures of the cell trenches 14 and the outer peripheral trenches 18 of the semiconductor device 100 may be the same as those of the semiconductor device 10 shown in FIG. 3. The semiconductor device 100 is different from the semiconductor device 10 in that the former includes three sets of cell trenches S1, S2, and S3.

The semiconductor device 100 may further include a gate wiring 102 formed on the insulating layer 16 and a source wire 104 formed on the insulating layer 16 and separated from the gate wiring 102. The gate wiring 102 and the source wiring 104 may be made of at least one of titanium (Ti), nickel (Ni), gold (Au), silver (Ag), copper (Cu), aluminum (Al), a copper alloy, and an aluminum alloy.

The gate wiring 102 may include a gate pad 106 arranged at one corner of the semiconductor layer 12, and gate fingers 108, 110, 112, and 114 in a plan view. The gate finger 108 extends from the gate pad 106 in the X-axis direction and may overlap some of the plurality of cell trenches 14 in a plan view. The gate finger 110 extends from the gate finger 108 in the Y-axis direction and may overlap some of the plurality of cell trenches 14 in a plan view. The gate finger 112 extends from the gate pad 106 in the Y-axis direction and may overlap some of the plurality of cell trenches 14 in a plan view. The gate finger 114 extends from the gate finger 112 in the X-axis direction and may overlap some of the plurality of cell trenches 14 in a plan view. The gate pad 106 and the gate fingers 108, 110, 112, and 114 may be integrally formed. The source line 104 may include an inner segment 116 at least partially surrounded by the gate wiring 102 in a plan view and an outer peripheral segment 118 at least partially surrounding the gate wiring 102. The inner segment 116 is connected to the outer peripheral segment 118 via a gap between the gate finger 110 and the gate finger 114. The inner segment 116 and the outer peripheral segment 118 may be integrally formed.

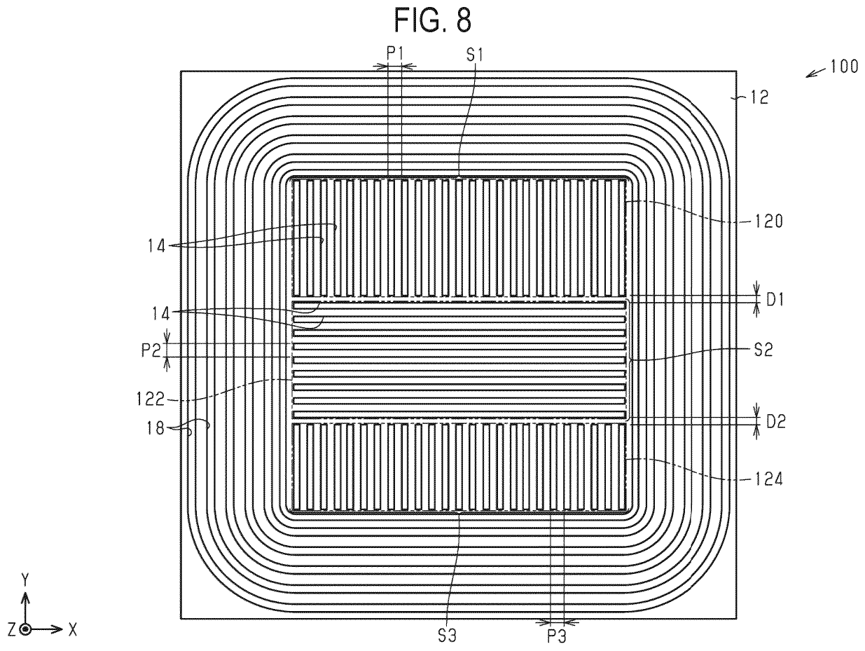

FIG. 8 is a schematic plan view showing the arrangement of the cell trenches 14 and the outer peripheral trenches 18 formed in the semiconductor layer 12 of the semiconductor device 100 shown in FIG. 7. To explain the arrangement of the cell trenches 14 and the outer peripheral trenches 18, the insulating layer 16, the gate wiring 102, and the source wiring 104 (see FIG. 7) are not illustrated in the semiconductor device 100 shown in FIG. 8.

The first set of cell trenches S1 is arranged at a first pitch P1 in the X-axis direction in a plan view. The second set of cell trenches S2 is arranged at a second pitch P2 in the Y-axis direction in a plan view. The third set of cell trenches S3 is arranged at a third pitch P3 in the X-axis direction in a plan view. The semiconductor layer 12 includes a first cell region 120 in which the first set of cell trenches S1 is arranged, a second cell region 122 in which the second set of cell trenches S2 is arranged, and a third cell region 124 in which the third set of cell trenches S3 is arranged. Each of the first cell region 120, the second cell region 122, and the third cell region 124 may be rectangular in a plan view. In the example of FIG. 8, the first cell region 120, the second cell region 122, and the third cell region 124 may be arranged in the Y-axis direction. Further, the second cell region 122 may be arranged between the first cell region 120 and the third cell region 124. The first cell region 120 in which the cell trenches 14 extending in the Y-axis direction are arranged is adjacent to the second cell region 122 in which the cell trenches 14 extending in a different direction, i.e., the X-axis direction, are arranged. The second cell region 122 in which the cell trenches 14 extending in the X-axis direction are arranged is adjacent to the third cell region 124 in which the cell trenches 14 extending in a different direction, i.e., the Y-axis direction, are arranged. The one or more outer peripheral trenches 18 are arranged to surround the first cell region 120, the second cell region 122, and the third cell region 124 in a plan view. More specifically, the one or more outer peripheral trenches 18 may form a loop surrounding the first cell region 120, the second cell region 122, and the third cell region 124 in a plan view. An inter-cell distance D1 between the first cell region 120 and the second cell region 122 is smaller than both the first pitch P1 and the second pitch P2. Further, an inter-cell distance D2 between the second cell region 122 and the third cell region 124 is smaller than both the second pitch P2 and the third pitch P3.

The inter-cell distance D1 may be a minimum distance between the first set of cell trenches S1 and the second set of cell trenches S2. More specifically, when the first cell region 120 and the second cell region 122 are arranged in the Y-axis direction, the inter-cell distance D1 may be the minimum distance between two or more cell trenches among the first set of cell trenches S1 and one cell trench located closest to the first cell region 120 among the second set of cell trenches S2.

The inter-cell distance D2 may be a minimum distance between the second set of cell trenches S2 and the third set of cell trenches S3. More specifically, when the second cell region 122 and the third cell region 124 are arranged in the Y-axis direction, the inter-cell distance D2 may be the minimum distance between one cell trench located closest to the third cell region 124 among the second set of cell trenches S2 and two or more cell trenches among the third set of cell trenches S3.

The first pitch P1 may be the same as or different from the second pitch P2. The second pitch P2 may be the same as or different from the third pitch P3. The third pitch P3 may be the same as or different from the first pitch P1.

As described above, in the semiconductor device 100 according to the first modification, one or more outer peripheral trenches 18 are arranged to surround the first cell region 120, the second cell region 122, and the third cell region 124 in a plan view. Further, the inter-cell distance D1 between the first cell region 120 and the second cell region 122 is smaller than both the first pitch P1 and the second pitch P2, and the inter-cell distance D2 between the second cell region 122 and the third cell region 124 is smaller than both the second pitch P2 and the third pitch P3. As a result, depletion layers formed in a region between the first cell region 120 and the second cell region 122 and a region between the second cell region 122 and the third cell region may be widened in the same manner as the cell regions 120, 122, and 124, and the cell regions 120, 122, and 124 may be relatively widened. Therefore, the on-resistance of the semiconductor device 100 may be reduced while ensuring the withstand voltage of the semiconductor device 100.

### [Second Modification]

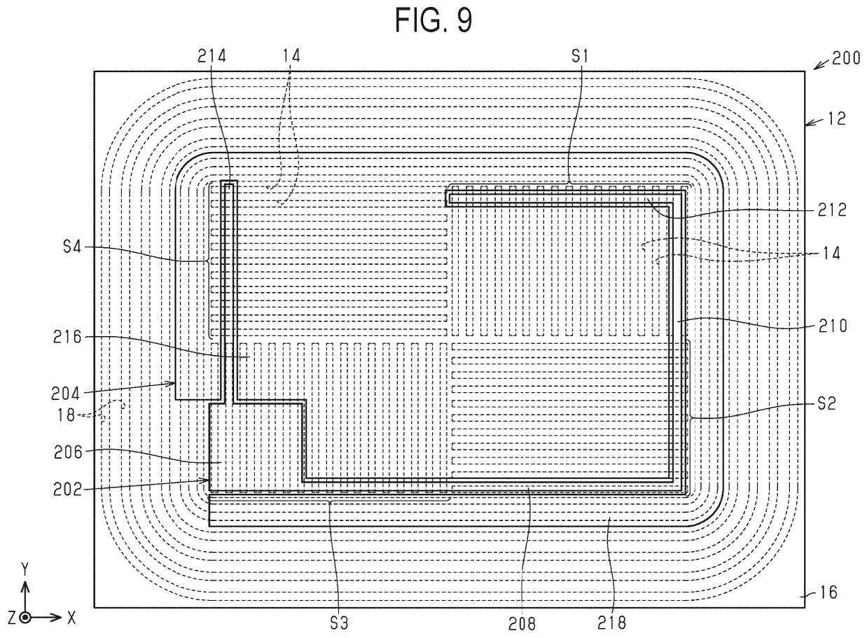

FIG. 9 is a schematic plan view of an exemplary semiconductor device 200 according to a second modification. In FIG. 9, the same components as those of the semiconductor device 10 shown in FIG. 1 are denoted by the same reference numerals. Detailed explanation of components similar to those of the semiconductor device 10 are omitted.

Like the semiconductor device 10, the semiconductor device 200 may be, for example, a metal insulating film semiconductor field effect transistor (MISFET) with a trench gate structure. The semiconductor device 200 includes a semiconductor layer 12, a plurality of cell trenches 14 formed in the semiconductor layer 12, and an insulating layer 16 formed on the semiconductor layer 12.

The plurality of cell trenches 14 includes a first set of cell trenches S1 extending in the Y-axis direction and arranged in the X-axis direction, a second set of cell trenches S2 extending in the X-axis direction and arranged in the Y-axis direction, a third set of cell trenches S3 extending in the Y-axis direction and arranged in the X-axis direction, and a fourth set of cell trenches S4 extending in the X-axis direction and arranged in the Y-axis direction. In the example of FIG. 9, the cell trenches 14 included in the first set may have the same length. The cell trenches 14 included in the second set may have the same length. The cell trenches 14 included in the third set may have the same length. The cell trenches 14 included in the fourth set may have the same length. The semiconductor device 200 further includes one or more outer peripheral trenches 18 formed in the semiconductor layer 12. The one or more outer peripheral trenches 18 may be arranged to surround the plurality of cell trenches 14.

The cross-sectional structures of the cell trenches 14 and the outer peripheral trenches 18 of the semiconductor device 200 may be the same as those of the semiconductor device 10 shown in FIG. 3. The semiconductor device 200 is different from the semiconductor device 10 in that the former includes four sets of cell trenches S1, S2, S3, and S4.

The semiconductor device 200 may further include a gate wire 202 formed on the insulating layer 16 and a source wire 204 formed on the insulating layer 16 and separated from the gate wiring 202. The gate wiring 202 and the source wiring 204 may be made of at least one selected from the group of titanium (Ti), nickel (Ni), gold (Au), silver (Ag), copper (Cu), aluminum (Al), a copper alloy, and an aluminum alloy.

The gate wiring 202 may include a gate pad 206 arranged at one corner of the semiconductor layer 12, and gate fingers 208, 210, 212, and 214 in a plan view. The gate finger 208 extends from the gate pad 206 in the X-axis direction and may overlap some of the plurality of cell trenches 14 in a plan view. The gate finger 210 extends from the gate finger 208 in the Y-axis direction and may overlap some of the plurality of cell trenches 14 in a plan view. The gate finger 212 extends from the gate finger 210 in the X-axis direction and may overlap some of the plurality of cell trenches 14 in a plan view. The gate finger 214 extends from the gate pad 206 in the Y-axis direction and may overlap some of the plurality of cell trenches 14 in a plan view. The gate pad 206 and the gate fingers 208, 210, 212, and 214 may be integrally formed. The source wiring 204 may include an inner segment 216 at least partially surrounded by the gate wiring 202 in a plan view and an outer peripheral segment 218 at least partially surrounding the gate wiring 202. The inner segment 216 is connected to the outer peripheral segment 218 via a gap between the gate finger 212 and the gate finger 214. The inner segment 216 and the outer peripheral segment 218 may be integrally formed.

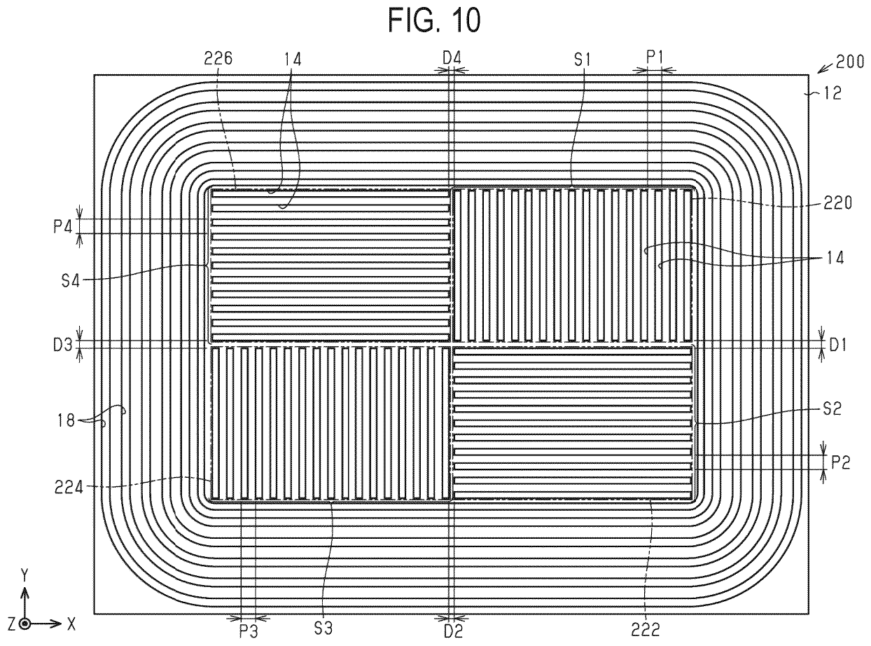

FIG. 10 is a schematic plan view showing the arrangement of the cell trenches 14 and the outer peripheral trenches 18 formed in the semiconductor layer 12 of the semiconductor device 200 shown in FIG. 9. For explaining the arrangement of the cell trenches 14 and the outer peripheral trenches 18, the insulating layer 16, the gate wiring 202, and the source wiring 204 (see FIG. 9) are omitted in the semiconductor device 200 shown in FIG. 10.

The first set of cell trenches S1 is arranged at a first pitch P1 in the X-axis direction in a plan view. The second set of cell trenches S2 is arranged at a second pitch P2 in the Y-axis direction in a plan view. The third set of cell trenches S3 is arranged at a third pitch P3 in the X-axis direction in a plan view. The fourth set of cell trenches S4 is arranged at a fourth pitch P4 in the Y-axis direction in a plan view. The semiconductor layer 12 includes a first cell region 220 in which the first set of cell trenches S1 is arranged, a second cell region 222 in which the second set of cell trenches S2 is arranged, a third cell region 224 in which the third set of cell trenches S3 is arranged, and a fourth cell region 226 in which the fourth set of cell trenches S4 is arranged. Each of the first cell region 220, the second cell region 222, the third cell region 224, and the fourth cell region 226 may be rectangular in a plan view. In the example of FIG. 10, the first cell region 220 and the second cell region 222 may be arranged in the Y-axis direction. The second cell region 222 and the third cell region 224 may be arranged in the X-axis direction. The third cell region 224 and the fourth cell region 226 may be arranged in the Y-axis direction. The fourth cell region 226 and the first cell region 220 may be arranged in the X-axis direction. The first cell region 220 and the third cell region 224 in which the cell trenches 14 extending in the Y-axis direction are arranged are adjacent to the second cell region 222 and the fourth cell region 226 in which the cell trenches 14 extending in a different direction, i.e., the X-axis direction, are arranged. The one or more outer peripheral trenches 18 are arranged to surround the first cell region 220, the second cell region 222, the third cell region 224, and the fourth cell region 226 in a plan view. More specifically, the one or more outer peripheral trenches 18 may form a loop surrounding the first cell region 220, the second cell region 222, the third cell region 224, and the fourth cell region 226 in a plan view. An inter-cell distance D1 between the first cell region 220 and the second cell region 222 is smaller than both the first pitch P1 and the second pitch P2. An inter-cell distance D2 between the second cell region 222 and the third cell region 224 is smaller than both the second pitch P2 and the third pitch P3. An inter-cell distance D3 between the third cell region 224 and the fourth cell region 226 is smaller than both the third pitch P3 and the fourth pitch P4. An inter-cell distance D4 between the fourth cell region 226 and the first cell region 220 is smaller than both the fourth pitch P4 and the first pitch P1.

The inter-cell distance D1 may be a minimum distance between the first set of cell trenches S1 and the second set of cell trenches S2. More specifically, when the first cell region 220 and the second cell region 222 are arranged in the Y-axis direction, the inter-cell distance D1 may be the minimum distance between two or more cell trenches among the first set of cell trenches S1 and one cell trench located closest to the first cell region 220 among the second set of cell trenches S2.

The inter-cell distance D2 may be a minimum distance between the second set of cell trenches S2 and the third set of cell trenches S3. More specifically, when the second cell region 222 and the third cell region 224 are arranged in the X-axis direction, the inter-cell distance D2 may be the minimum distance between two or more cell trenches among the second set of cell trenches S2 and one cell trench located closest to the second cell region 222 among the third set of cell trenches S3.

The inter-cell distance D3 may be a minimum distance between the third set of cell trenches S3 and the fourth set of cell trenches S4. More specifically, when the third cell region 224 and the fourth cell region 226 are arranged in the Y-axis direction, the inter-cell distance D3 may be the minimum distance between two or more cell trenches among the third set of cell trenches S3 and one cell trench located closest to the third cell region 224 among the fourth set of cell trenches S4.

The inter-cell distance D4 may be a minimum distance between the fourth set of cell trenches S4 and the first set of cell trenches S1. More specifically, when the fourth cell region 226 and the first cell region 220 are arranged in the X-axis direction, the inter-cell distance D4 may be the minimum distance between two or more cell trenches among the fourth set of cell trenches S4 and one cell trench located closest to the fourth cell region 226 among the first set of cell trenches S1.

The first pitch P1 may be the same as or different from the second pitch P2. The second pitch P2 may be the same as or different from the third pitch P3. The third pitch P3 may be the same as or different from the fourth pitch P4. The fourth pitch P4 may be the same as or different from the first pitch P1. The first pitch P1 may be the same as or different from the third pitch P3.

As described above, in the semiconductor device 200 according to the second modification, one or more outer peripheral trenches 18 are arranged to surround the first cell region 220, the second cell region 222, the third cell region 224, and the fourth cell region 226 in a plan view. Further, the inter-cell distance D1 between the first cell region 220 and the second cell region 222 is smaller than both the first pitch P1 and the second pitch P2, the inter-cell distance D2 between the second cell region 222 and the third cell region 224 is smaller than both the second pitch P2 and the third pitch P3, the inter-cell distance D3 between the third cell region 224 and the fourth cell region 226 is smaller than both the third pitch P3 and the fourth pitch P4, and the inter-cell distance D4 between the fourth cell region 226 and the first cell region 220 is smaller than both the fourth pitch P4 and the first pitch P1. As a result, depletion layers formed in a region between the first cell region 220 and the second cell region 222, a region between the second cell region 222 and the third cell region 224, a region between the third cell region 224 and the fourth cell region 226, and a region between the fourth cell region 226 and the first cell region 220 may be widened in the same way as in the cell regions 220, 222, 224, and 226, and the cell regions 220, 222, 224, and 226 may be relatively widened. Therefore, the on-resistance of the semiconductor device 200 may be reduced while ensuring the withstand voltage of the semiconductor device 200.

### [Other Modifications]

Each of the above-described embodiments and modifications may be modified and implemented as follows.
The number, shape, and arrangement of cell regions included in the semiconductor layer 12 are arbitrary, and are not limited to the above-described examples. For example, two adjacent cell regions may include cell trenches of different lengths extending in the same direction.
The layout of the gate wiring 20 and the source wiring 22 is not limited to the above-described examples. For example, the source wiring 22 may include only the inner segment 32 and may not include the outer peripheral segment 34.
A structure in which the conductivity type of each region in the semiconductor layer 12 is reversed may be adopted. That is, the p-type region may be an n-type region, and the n-type region may be a p-type region.
An additional wiring structure may be formed on a layer including the gate wiring 20 and the source wiring 22.

One or more of the various examples described in the present disclosure may be combined unless technically contradictory. In the present disclosure, the description “at least one of A and B” should be understood as meaning “only A, only B, or both A and B.”

The term “on” as used herein includes the meanings of “on” and “above” unless the context explicitly indicates otherwise. Thus, the expression “a first layer is formed on a second layer” means that in some embodiments the first layer may be arranged directly on the second layer in contact with the second layer, but in other embodiments the first layer may be arranged above the second layer with no contact with the second layer. That is, the term “on” does not exclude a structure in which other layers are formed between the first layer and the second layer.

As used herein, the terms indicating directions, such as “vertical,” “horizontal,” “upward,” “downward,” “upper,” “lower,” “forward,” “backward,” “longitudinal,” “lateral,” “left,” “right,” “front,” “back,” and the like, depend on the particular orientation of a device being described and illustrated. A variety of alternative orientations may be envisioned in the present disclosure, and thus these directional terms should not be interpreted in a narrow sense.

For example, the Z-axis direction used in the present disclosure may not be the vertical direction, and may not completely match the vertical direction. For example, the X-axis direction may be the vertical direction, or the Y-axis direction may be the vertical direction.

### [Supplementary Notes]

The technical ideas that may be understood from the above-described embodiments and modifications are described below. It should be noted that the corresponding reference numerals in the embodiments are shown in parentheses for the configurations described in the supplementary notes for the purpose of aiding understanding and not for the purpose of limitation. Reference numerals are shown as examples to aid understanding, and the components described in each supplementary note should not be limited to the components indicated by the reference numerals.

### (Supplementary Note 1)

A semiconductor device including:
a semiconductor layer (12);
a plurality of cell trenches (14) formed in the semiconductor layer (12);
an insulating layer (16) formed on the semiconductor layer (12);
a plurality of electrodes (56), each embedded in a corresponding one of the plurality of cell trenches (14) via the insulating layer (16); and
one or more outer peripheral trenches (18) formed in the semiconductor layer (12),
wherein the plurality of cell trenches (14) includes:
a first set of cell trenches (S1) extending in a first direction and arranged at a first pitch (P1) in a second direction orthogonal to the first direction in a plan view; and
a second set of cell trenches (S2) extending in the second direction and arranged at a second pitch (P2) in the first direction,
wherein the semiconductor layer (12) includes a first cell region (36; 120; 220) in which the first set of cell trenches (S1) is arranged and a second cell region (38; 122; 222) in which the second set of cell trenches (S2) is arranged, and the one or more outer peripheral trenches (18) are arranged to surround the first cell region (36; 120; 220) and the second cell region (38; 122; 222) in the plan view, and
wherein an inter-cell distance (D, D1) between the first cell region (36; 120; 220) and the second cell region (38; 122; 222) is smaller than both the first pitch (P1) and the second pitch (P2).

### (Supplementary Note 2)

The semiconductor device of Supplementary Note 1, wherein the first set of cell trenches (S1) is arranged at a first spacing (Sp1), the second set of cell trenches (S2) is arranged at a second spacing (Sp2), and the inter-cell distance (D, D1) is smaller than both the first spacing (Sp1) and the second spacing (Sp2).

### (Supplementary Note 3)

The semiconductor device of Supplementary Note 1 or 2, wherein the inter-cell distance (D, D1) is a minimum distance between the first set of cell trenches (S1) and the second set of cell trenches (S2).

### (Supplementary Note 4)

The semiconductor device of any one of Supplementary Notes 1 to 3, wherein the first cell region (36) and the second cell region (38) are arranged in the second direction, and
wherein the inter-cell distance (D) is a minimum distance between one cell trench located closest to the second cell region (38) among the first set of cell trenches (S1) and two or more cell trenches among the second set of cell trenches (S2).

### (Supplementary Note 5)

The semiconductor device of any one of Supplementary Notes 1 to 4, wherein the plurality of cell trenches (14) includes a plurality of gate trenches (52),
wherein the plurality of electrodes (56) includes a plurality of gate electrodes (58), and
wherein each of the plurality of gate electrodes (58) is embedded in a corresponding one of the plurality of gate trenches (52) via the insulating layer (16).

### (Supplementary Note 6)

The semiconductor device of Supplementary Note 5, wherein the plurality of electrodes (56) includes a plurality of first field plate electrodes (60), and
wherein each of the plurality of first field plate electrodes (60) is embedded in the corresponding one of the plurality of gate trenches (52) via the insulating layer (16) while being separated from each of the plurality of gate electrodes (58).

### (Supplementary Note 7)

The semiconductor device of Supplementary Note 6, further including: a gate wiring (20) formed on the insulating layer (16) and a source wiring (22) formed on the insulating layer (16) and separated from the gate wiring (20),
wherein the plurality of gate electrodes (58) is electrically connected to the gate wiring (20), and
wherein the plurality of first field plate electrodes (60) is electrically connected to the source wiring (22).

### (Supplementary Note 8)

The semiconductor device of Supplementary Note 5 or 6, wherein the plurality of cell trenches (14) includes a field plate trench (54), and
wherein the plurality of electrodes (56) includes a second field plate electrode (80) embedded in the field plate trench (54) via the insulating layer (16), and each of the plurality of gate electrodes (58) is not embedded in the field plate trench (54).

### (Supplementary Note 9)

The semiconductor device of Supplementary Note 8, further including: a gate wiring (20) formed on the insulating layer (16) and a source wiring (22) formed on the insulating layer (16) and separated from the gate wiring (20),
wherein the plurality of gate electrodes (58) is electrically connected to the gate wiring (20), and
wherein the second field plate electrode (80) is electrically connected to the source wiring (22).

### (Supplementary Note 10)

The semiconductor device of Supplementary Note 8 or 9, wherein the first cell region (36) and the second cell region (38) are arranged in the second direction, and
wherein a cell trench (14) located closest to the second cell region (38) among the first set of cell trenches (S1) is the field plate trench (54).

### (Supplementary Note 11)

The semiconductor device of any one of Supplementary Notes 1 to 10, further including one or more outer peripheral electrodes (68), each of the one or more outer peripheral electrodes (68) being embedded in a corresponding one of the one or more outer peripheral trenches (18) via the insulating layer (16).

### (Supplementary Note 12)

The semiconductor device of Supplementary Note 11, further including a gate wiring (20) formed on the insulating layer (16) and a source wiring (22) formed on the insulating layer (16) and separated from the gate wiring (20),
wherein at least one of the one or more outer peripheral electrodes (68) is electrically connected to the source wiring (22).

### (Supplementary Note 13)

The semiconductor device of any one of Supplementary Notes 1 to 12, wherein the one or more outer peripheral trenches (18) include a plurality of outer peripheral trenches (18),
wherein the plurality of outer peripheral trenches (18) includes:
a first outer peripheral trench (70) which is an innermost outer peripheral trench among the plurality of outer peripheral trenches; and
one or more second outer peripheral trenches (72) surrounding the first outer peripheral trench in a plan view, and
wherein each of the one or more second outer peripheral trenches (72) has a width larger than that of the first outer peripheral trench (70).

### (Supplementary Note 14)

The semiconductor device of any one of Supplementary Notes 1 to 13, wherein the semiconductor layer (12) includes a drift region (44) of a first conductivity type, a body region (46) of a second conductivity type formed on the drift region (44), and a source region (48) of the first conductivity type formed on the body region (46), and
wherein each cell trench (14) reaches the drift region (44) through the source region (48) and the body region (46).

### (Supplementary Note 15)

The semiconductor device of any one of Supplementary Notes 1 to 14, wherein the first pitch (P1) is the same as the second pitch (P2).

### (Supplementary Note 16)

The semiconductor device of any one of Supplementary Notes 1 to 14, wherein the first pitch (P1) is different from the second pitch (P2).

### (Supplementary Note 17)

The semiconductor device of any one of Supplementary Notes 1 to 16, wherein each of the first cell region (36; 120; 220) and the second cell region (38; 122; 222) has a rectangular shape in the plan view.

### (Supplementary Note 18)

The semiconductor device of any one of Supplementary Notes 1 to 17, wherein the one or more outer peripheral trenches (18) form a loop surrounding the first cell region (36; 120; 220) and the second cell region (38; 122; 222) in the plan view.

### (Supplementary Note 19)

The semiconductor device of Supplementary Note 1, wherein the plurality of cell trenches (14) further includes a third set of cell trenches (S3) extending in the first direction and arranged at a third pitch (P3) in the second direction,
wherein the semiconductor layer (12) further includes a third cell region (124) in which the third set of cell trenches (S3) is arranged,
wherein the one or more outer peripheral trenches (18) is arranged to surround the first cell region (120), the second cell region (122), and the third cell region (124) in a plan view,
wherein the first cell region (120), the second cell region (122), and the third cell region (124) are arranged in the first direction, and the second cell region (122) is arranged between the first cell region (120) and the third cell region (124), and
wherein an inter-cell distance (D2) between the second cell region (122) and the third cell region (124) is smaller than both the second pitch (P2) and the third pitch (P3).

### (Supplementary Note 20)

The semiconductor device of Supplementary Note 1, wherein the plurality of cell trenches (14) further includes:
a third set of cell trenches (S3) extending in the first direction and arranged at a third pitch (P3) in the second direction; and
a fourth set of cell trenches (S4) extending in the second direction and arranged at a fourth pitch (P4) in the first direction,
wherein the semiconductor layer (12) further includes a third cell region (224) in which the third set of cell trenches (S3) is arranged, and a fourth cell region (226) in which the fourth set of cell trenches (S4) is arranged,
wherein the one or more outer peripheral trenches (18) are arranged to surround the first cell region (220), the second cell region (222), the third cell region (224), and the fourth cell region (226) in the plan view,
wherein the first cell region (220) and the second cell region (222) are arranged in the first direction,
wherein the second cell region (222) and the third cell region (224) are arranged in the second direction,
wherein the third cell region (224) and the fourth cell region (226) are arranged in the first direction,
wherein the fourth cell region (226) and the first cell region (220) are arranged in the second direction,
wherein an inter-cell distance (D2) between the second cell region (222) and the third cell region (224) is smaller than both the second pitch (P2) and the third pitch (P3),
wherein an inter-cell distance (D3) between the third cell region (224) and the fourth cell region (226) is smaller than both the third pitch (P3) and the fourth pitch (P4), and
wherein an inter-cell distance (D4) between the fourth cell region (226) and the first cell region (220) is smaller than both the fourth pitch (P4) and the first pitch (P1).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor layer;
a plurality of cell trenches formed in the semiconductor layer;
an insulating layer formed on the semiconductor layer;
a plurality of electrodes, each embedded in a corresponding one of the plurality of cell trenches via the insulating layer; and
one or more outer peripheral trenches formed in the semiconductor layer,
wherein the plurality of cell trenches includes:
a first set of cell trenches extending in a first direction and arranged at a first pitch in a second direction orthogonal to the first direction in a plan view; and
a second set of cell trenches extending in the second direction and arranged at a second pitch in the first direction,
wherein the semiconductor layer includes a first cell region in which the first set of cell trenches is arranged and a second cell region in which the second set of cell trenches is arranged, and the one or more outer peripheral trenches are arranged to surround the first cell region and the second cell region in the plan view, and
wherein an inter-cell distance between the first cell region and the second cell region is smaller than both the first pitch and the second pitch.

2. The semiconductor device of claim 1, wherein the first set of cell trenches is arranged at a first spacing, the second set of cell trenches is arranged at a second spacing, and the inter-cell distance is smaller than both the first spacing and the second spacing.

3. The semiconductor device of claim 1, wherein the inter-cell distance is a minimum distance between the first set of cell trenches and the second set of cell trenches.

4. The semiconductor device of claim 1, wherein the first cell region and the second cell region are arranged in the second direction, and
wherein the inter-cell distance is a minimum distance between one cell trench located closest to the second cell region among the first set of cell trenches and two or more cell trenches among the second set of cell trenches.

5. The semiconductor device of claim 1, wherein the plurality of cell trenches includes a plurality of gate trenches,
wherein the plurality of electrodes includes a plurality of gate electrodes, and
wherein each of the plurality of gate electrodes is embedded in a corresponding one of the plurality of gate trenches via the insulating layer.

6. The semiconductor device of claim 5, wherein the plurality of electrodes includes a plurality of first field plate electrodes, and
wherein each of the plurality of first field plate electrodes is embedded in the corresponding one of the plurality of gate trenches via the insulating layer while being separated from each of the plurality of gate electrodes.

7. The semiconductor device of claim 6, further comprising a gate wiring formed on the insulating layer and a source wiring formed on the insulating layer and separated from the gate wiring,
wherein the plurality of gate electrodes is electrically connected to the gate wiring, and
wherein the plurality of first field plate electrodes is electrically connected to the source wiring.

8. The semiconductor device of claim 5, wherein the plurality of cell trenches includes a field plate trench, and
wherein the plurality of electrodes includes a second field plate electrode embedded in the field plate trench via the insulating layer, and
wherein each of the plurality of gate electrodes is not embedded in the field plate trench.

9. The semiconductor device of claim 8, further comprising a gate wiring formed on the insulating layer and a source wiring formed on the insulating layer and separated from the gate wiring,
wherein the plurality of gate electrodes is electrically connected to the gate wiring, and
wherein the second field plate electrode is electrically connected to the source wiring.

10. The semiconductor device of claim 8, wherein the first cell region and the second cell region are arranged in the second direction, and
wherein a cell trench located closest to the second cell region among the first set of cell trenches is the field plate trench.

11. The semiconductor device of claim 1, further comprising one or more outer peripheral electrodes, each of the one or more outer peripheral electrodes being embedded in a corresponding one of the one or more outer peripheral trenches via the insulating layer.

12. The semiconductor device of claim 11, further comprising a gate wiring formed on the insulating layer and a source wiring formed on the insulating layer and separated from the gate wiring,
wherein at least one of the one or more outer peripheral electrodes is electrically connected to the source wiring.

13. The semiconductor device of claim 1, wherein the one or more outer peripheral trenches include a plurality of outer peripheral trenches,
wherein the plurality of outer peripheral trenches includes:
a first outer peripheral trench which is an innermost outer peripheral trench among the plurality of outer peripheral trenches; and
one or more second outer peripheral trenches surrounding the first outer peripheral trench in the plan view, and
wherein each of the one or more second outer peripheral trenches has a width larger than that of the first outer peripheral trench.

14. The semiconductor device of claim 1, wherein the semiconductor layer includes a drift region of a first conductivity type, a body region of a second conductivity type formed on the drift region, and a source region of the first conductivity type formed on the body region, and
wherein each cell trench reaches the drift region through the source region and the body region.

15. The semiconductor device of claim 1, wherein the first pitch is the same as the second pitch.

16. The semiconductor device of claim 1, wherein the first pitch is different from the second pitch.

17. The semiconductor device of claim 1, wherein each of the first cell region and the second cell region has a rectangular shape in the plan view.

18. The semiconductor device of claim 1, wherein the one or more outer peripheral trenches form a loop surrounding the first cell region and the second cell region in the plan view.

19. The semiconductor device of claim 1, wherein the plurality of cell trenches further includes a third set of cell trenches extending in the first direction and arranged at a third pitch in the second direction,
wherein the semiconductor layer further includes a third cell region in which the third set of cell trenches is arranged,
wherein the one or more outer peripheral trenches are arranged to surround the first cell region, the second cell region, and the third cell region in the plan view,
wherein the first cell region, the second cell region, and the third cell region are arranged in the first direction, and the second cell region is arranged between the first cell region and the third cell region, and
wherein an inter-cell distance between the second cell region and the third cell region is smaller than both the second pitch and the third pitch.

20. The semiconductor device of claim 1, wherein the plurality of cell trenches further includes:
a third set of cell trenches extending in the first direction and arranged at a third pitch in the second direction; and
a fourth set of cell trenches extending in the second direction and arranged at a fourth pitch in the first direction,
wherein the semiconductor layer further includes a third cell region in which the third set of cell trenches is arranged, and a fourth cell region in which the fourth set of cell trenches is arranged,
wherein the one or more outer peripheral trenches are arranged to surround the first cell region, the second cell region, the third cell region, and the fourth cell region in the plan view,
wherein the first cell region and the second cell region are arranged in the first direction,
wherein the second cell region and the third cell region are arranged in the second direction,
wherein the third cell region and the fourth cell region are arranged in the first direction,
wherein the fourth cell region and the first cell region are arranged in the second direction,
wherein an inter-cell distance between the second cell region and the third cell region is smaller than both the second pitch and the third pitch,
wherein an inter-cell distance between the third cell region and the fourth cell region is smaller than both the third pitch and the fourth pitch, and
wherein an inter-cell distance between the fourth cell region and the first cell region is smaller than both the fourth pitch and the first pitch.
